(19) United States
(12) Patent Application Publication
(10) Pub. No.: US 2024/0147643 A1
(43) Pub. Date: May 2, 2024

(54) FLEXABLE LINKAGES FOR ACCESS PANEL ASSEMBLIES

(71) Applicant: HEWLETT-PACKARD DEVELOPMENT COMPANY, L.P., Spring, TX (US)

(72) Inventors: Ken Maclean, Spring, TX (US); Rudy Widiaman, Spring, TX (US); Brian Kirk Walters, Fort Collins, CO (US)

(73) Assignee: HEWLETT-PACKARD DEVELOPMENT COMPANY, L.P., Spring, TX (US)

(21) Appl. No.: 17/976,019

(22) Filed: Oct. 28, 2022

(51) Int. Cl. H05K 5/02

(52) U.S. Cl. CPC H05K 5/0221; H05K 5/023

(57) ABSTRACT

In one example in accordance with the present disclosure, a flexible linkage for a panel release mechanism is described. The example flexible linkage includes a body formed with a fold structure that unfolds from a first position to a second position under tension and becomes taut upon unfolding. The example flexible linkage also includes a first end of the body to couple to a handle of the panel release mechanism. The example flexible linkage also includes a second end of the body to couple to a latch mechanism.

### BACKGROUND

Enclosures are used to house and protect objects. For example, an enclosure may house delicate electronic components. Electronic technology has advanced to become virtually ubiquitous in society and has been used to enhance many activities in society. In other examples, enclosures may provide a storage area for non-electronic objects.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a perspective view of an enclosure with an access panel assembly, according to an example.

FIG. 2 is a front perspective view of an access panel assembly, according to an example.

FIG. 3 is a back perspective view of the access panel assembly, according to an example.

FIG. 4 is an exploded perspective view of the access panel assembly, according to an example.

FIG. 5 is a perspective view of a flexible linkage, according to an example.

FIG. 6 is a perspective view of a flexible linkage, according to another example.

FIGS. 7A-7C illustrate a front perspective view of the panel release mechanism moving from a closed position to an open position, according to an example.

FIGS. 8A-8C illustrate a back perspective view of the panel release mechanism moving from the closed position to the open position, according to an example.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

Enclosures are used to house and protect objects. For example, an enclosure may house delicate electronic components. Electronic technology has advanced to become virtually ubiquitous in society and has been used to enhance many activities in society. In other examples, enclosures may provide a storage area for non-electronic objects. Examples of electronic devices include circuit boards (e.g., mother boards) processors (e.g., central processing units (CPUs), graphics processing units (GPUs)), storage devices (e.g., hard drives, solid-state drives (SSDs), optical storage devices) power supplies (e.g., batteries, wired power supplies), computing devices, tablet devices, graphic tablets, multi-touch devices, wireless communication devices, game consoles, smart appliances, drones, robots, smart appliances, etc.

In some examples, access to an enclosure may be provided by an access panel. As used herein, an access panel is a movable barrier that selectively grants or restricts physical access to an interior of an enclosure. In some examples, an access panel includes panel release mechanism to selectively engage and disengage the access panel with the enclosure. Some approaches to implementing the panel release mechanism include a number of rigid linkages. In these approaches, because the linkages are rigid, the panel release mechanism may include many components, which increase the complexity and cost of the panel release mechanism.

The present specification describes examples of access panel assemblies that include a flexible linkage. In these examples, the flexible linkage may reduce the complexity of the panel release mechanism.

This specification discloses an example of a flexible linkage for a panel release mechanism. The example flexible linkage includes a body formed with a fold structure that unfolds from a first position to a second position under tension and becomes taut upon unfolding. The example flexible linkage also includes a first end of the body to couple to a handle of the panel release mechanism. The example flexible linkage also includes a second end of the body to couple to a latch mechanism.

In another example, the present specification also describes panel release mechanism. The example panel release mechanism includes a handle to rotate about an axis from a closed position to an open position. The example panel release mechanism also includes a latch mechanism to engage a catch. The example panel release mechanism further includes a flexible linkage connected to the handle at a first end of the flexible linkage, and connected to the latch mechanism at a second end of the flexible linkage. The flexible linkage includes a fold structure to allow the flexible linkage to unfold when the handle is partially rotated to the open position, and to actuate the latch mechanism after unfolding.

In yet another example, the present specification also describes an access panel assembly for an enclosure. The example access panel assembly includes a panel to provide access to the enclosure. The panel includes an opening. The access panel assembly also includes a handle connected to the panel at the opening of the panel. The handle is to rotate about an axis from a closed position to an open position. The access panel assembly further includes a latch mechanism connected to an interior surface of the panel. The latch mechanism is to selectively engage a catch located on the enclosure. The access panel assembly also includes a flexible linkage connected to the handle at a first end of the flexible linkage, and connected to the latch mechanism at a second end of the flexible linkage. The flexible linkage includes a fold structure to unfold from a retracted position to an extended position when the handle is rotated, and to actuate the latch mechanism after unfolding.

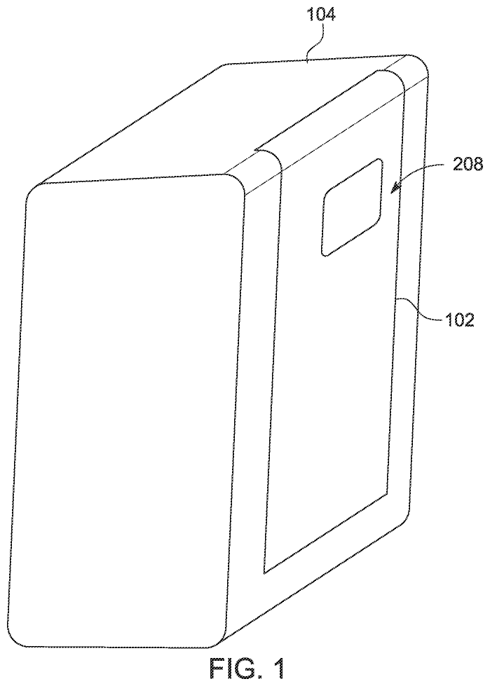

Turning now to the figures, FIG. 1 is a perspective view of an enclosure 104 with an access panel assembly 102, according to an example. In the example of FIG. 1, the enclosure 104 is depicted as a primarily rectangular prism. However, the enclosure 104 may be implemented with different geometries to accommodate different applications and/or objects. In some examples, the enclosure 104 may include an interior cavity (not shown) to house an object or multiple objects. For example, the enclosure 104 may be a case for an electronic device.

In some examples, an access panel assembly 102 may provide access to the interior of the enclosure 104. In some examples, the access panel assembly 102 may be moveable (e.g., may rotate on a hinge) to grant access to the enclosure 104. In some examples, the access panel assembly 102 may be detachable from the enclosure 104.

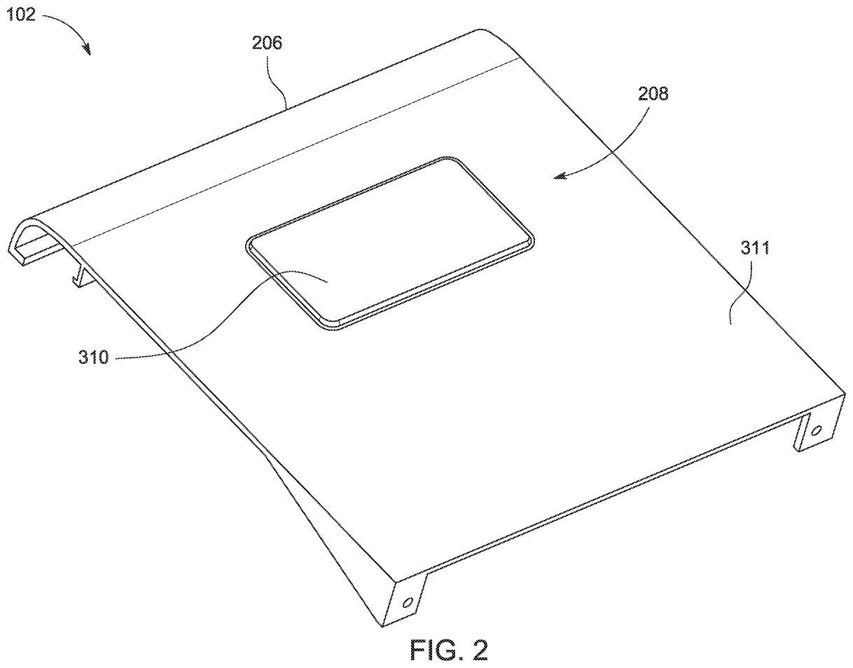

FIG. 2 is a front perspective view of an access panel assembly 102, according to an example. The access panel assembly 102 includes a panel 206 and a panel release mechanism 208. In some examples, the panel 206 may have a primarily planar form. In some examples, the panel 206 may be formed with a contour to match a corresponding enclosure (e.g., FIG. 1, 104). For example, the panel 206 in the example of FIG. 2 includes a curved end to match the contour of the enclosure.

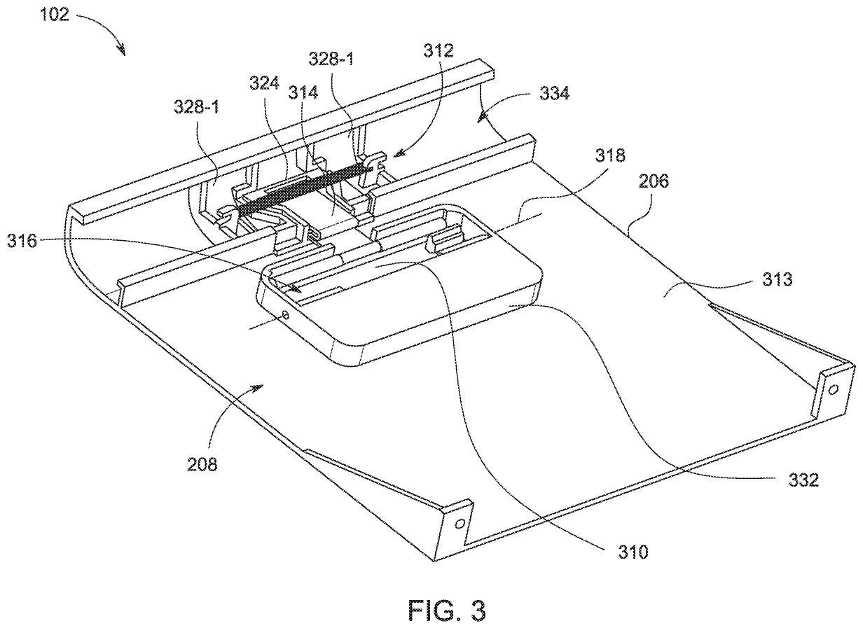

The panel 206 may include structures to receive and accommodate the panel release mechanism 208. For example, the panel 206 may include a recess on an exterior surface 311 to allow the handle 310 to lay in-plane with the exterior surface 311 when the handle 310 is in a closed position. The panel 206 may also include an opening (shown in FIG. 3) through which a portion of the handle 310 rotates.

FIG. 3 is a back perspective view of the access panel assembly 102, according to an example. The access panel assembly 102 includes a panel 206 and a panel release mechanism 208. The panel release mechanism 208 may include a handle 310, a latch mechanism 312, and a flexible linkage 314 as described herein.

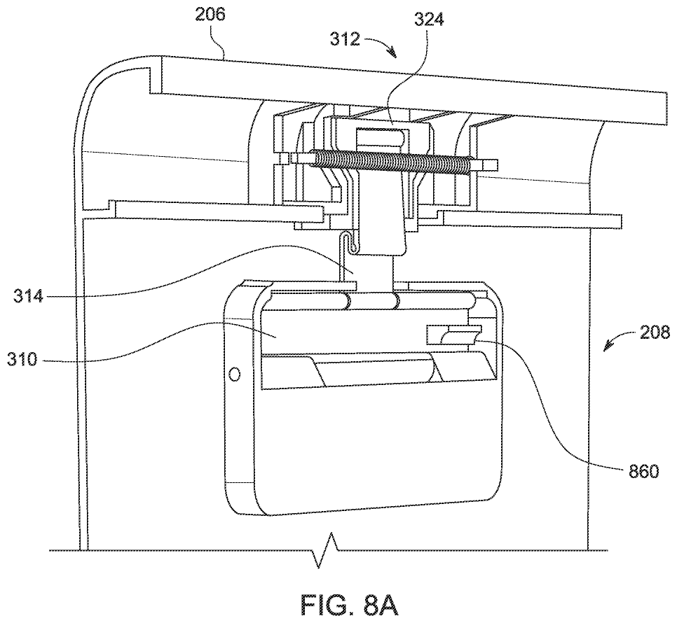

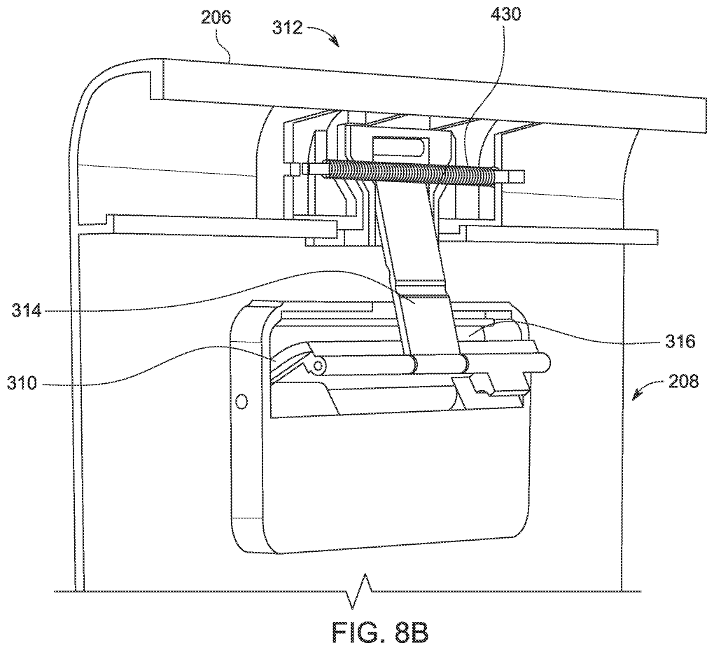

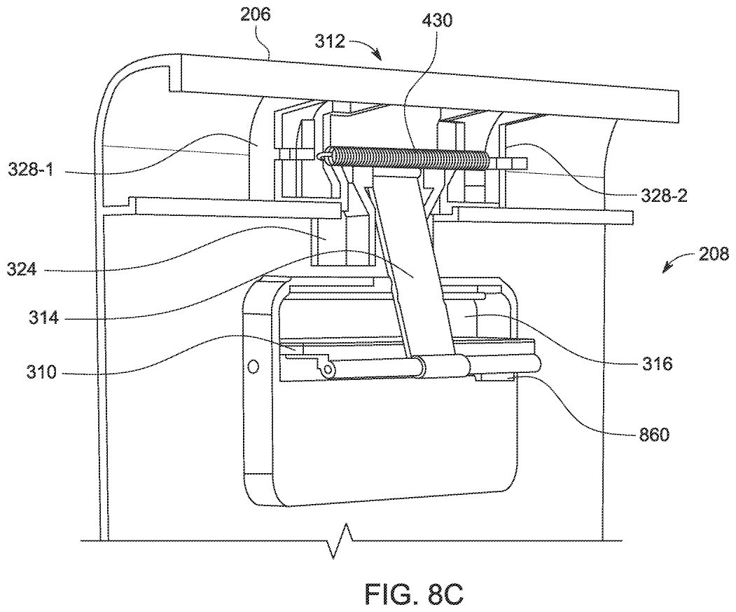

The panel 206 may include an opening 316 to allow the handle 310 to rotate. In some examples, the panel 206 may include a handle support structure 332 to allow the handle 310 to connect to the panel 206. The handle support structure 332 may be formed on or attached to an interior surface 313. In some examples, the handle support structure 332 may be formed to allow the handle 310 to rotate about an axis 318. In some examples, the axis 318 may be defined by a hole, channel, or other structure in the handle support structure 332 used to connect (e.g., via a pin) the handle 310. The handle 310 may rotate about the axis 318 from a closed position to an open position. In FIG. 3, the handle 310 is depicted in the closed position. An example showing the handle 310 in an open position is shown in FIG. 8C.

The panel release mechanism 208 includes a latch mechanism 312 to engage a catch (not shown) on the enclosure. The latch mechanism 312 may be connected to the interior surface 313 of the panel 206. The latch mechanism 312 may selectively engage a catch located on the enclosure. For example, rotation of the handle 310 by a user may cause the latch mechanism 312 to disengage or engage the catch located on the enclosure.

In the example of FIG. 3, the latch mechanism 312 includes a drive wedge 324 and a pair of catch engagement devices 328-1, 328-2. The drive wedge 324 includes two sloped (e.g., angled) side surfaces. The catch engagement devices 328-1, 328-2 each include a sloped surface to engage the sloped side surfaces of the drive wedge 324.

As the drive wedge 324 is forced to move along a first translation axis (e.g., a vertical axis) in a first direction (e.g., a vertical direction), the drive wedge 324 presses against the catch engagement devices 328-1, 328-2, which pushes the catch engagement devices 328-1, 328-2 to move along a second translation axis (e.g., horizontal axis). Upon moving a threshold distance, the catch engagement devices 328-1, 328-2 disengage from the catch of the enclosure, which releases the panel 206 and allows the panel 206 to move. It should be noted that the latch mechanism 312 may be implemented with other structures to engage and disengage from the enclosure.

In some examples, the panel 206 includes a channel 334 or other structure to guide the catch engagement devices 328-1, 328-2. The channel 334 may allow the catch engagement devices 328-1, 328-2 to move in the second direction (e.g., horizontal direction) in response to the force exerted by the drive wedge 324. In some examples, the drive wedge 324 includes tabs that engage the catch engagement devices 328-1, 328-2 when the catch engagement devices 328-1, 328-2 are installed in the channel 334. The tabs permit the drive wedge 324 to move in the first direction (e.g., a vertical direction) while restricting movement of the drive wedge 324 in other directions.

The panel release mechanism 208 also includes flexible linkage 314 connected to the handle 310 at a first end of the flexible linkage 314, and connected to the latch mechanism 312 at a second end of the flexible linkage 314. In the example of FIG. 3, the flexible linkage 314 connects to the drive wedge 324 and the handle 310 using pins.

The flexible linkage 314 includes a fold structure to allow the flexible linkage 314 to unfold when the handle 310 is partially rotated to the open position. After unfolding, the flexible linkage 314 actuates the latch mechanism 312. As used herein “actuate” refers to moving or activating the latch mechanism. Thus, during a first unfolding of the flexible linkage 314 during rotation of the handle, the flexible linkage 314 may not exert a force on the latch mechanism 312 sufficient to move or activate the latch mechanism 312. Once the flexible linkage 314 completes the unfolding, the fold structure may become taut after unfolding.

Once the fold structure becomes taut, then the flexible linkage 314 may exert a force on the latch mechanism 312 to actuate the latch mechanism 312. In the example of FIG. 3, the flexible linkage 314 may cause the drive wedge 324 to move along the first translation axis, which in turn, forces the catch engagement devices 328-1, 328-2 to move along the second translation axis.

It should be noted that unfolding of the fold structure of the flexible linkage 314 generates a bias force within the flexible linkage 314. Thus, the bias force generated by the fold structure is to be exerted on the handle 310 to cause the handle 310 to return to the closed position. In other words, when a user ceases to apply a force to open the handle, the bias force generated by the fold structure of the flexible linkage 314 causes the handle 310 to return to the closed position. Furthermore, the bias force generated by the flexible linkage 314 may keep the handle 310 from wobbling when the handle 310 is in the closed position.

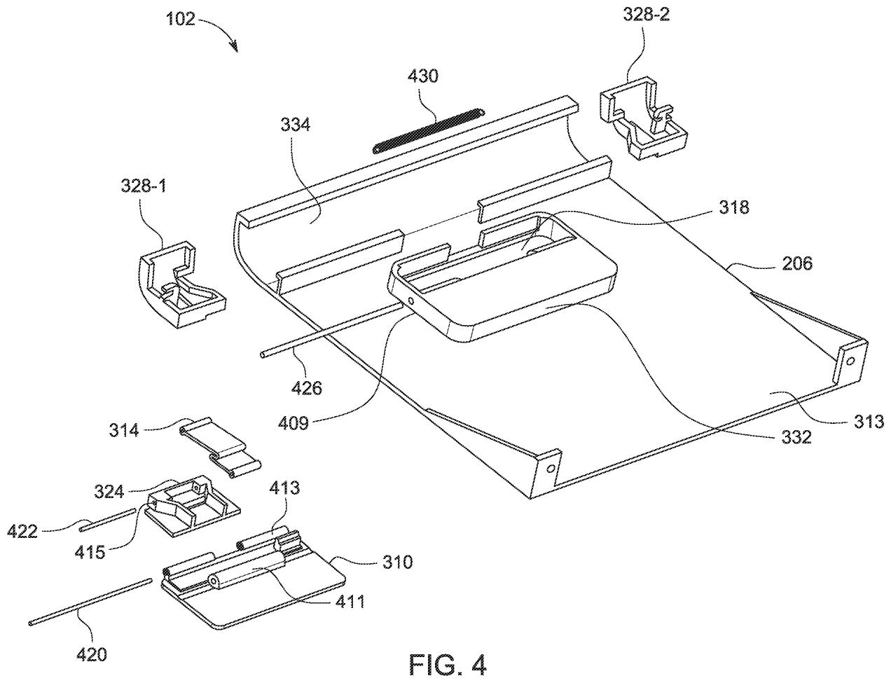

FIG. 4 is an exploded perspective view of the access panel assembly 102, according to an example. The panel 206 includes a handle support structure 332 with an opening 316. The handle support structure 332 includes a hole structure 409 to receive a pin 426 to connect to a first hole structure 411 of the handle 310. The pin 426 allows the handle 310 to rotate about the axis 318.

The handle 310 includes a second hole structure 413 offset from the first hole structure 411. The second hole structure 413 may be sized to receive a linkage pin 420. Thus, the flexible linkage 314 may be connected to the handle 310 by the linkage pin 420 offset from the axis 318 of rotation of the handle 310.

The latch mechanism includes a drive wedge 324 and an engagement device. In the example, of FIG. 4, the engagement device includes a pair of catch engagement devices 328-1, 328-2 as described in FIG. 3.

The drive wedge 324 is coupled to the flexible linkage 314. For example, drive wedge 324 includes a hole structure 415 to receive a pin 422 to connect to the second end of the flexible linkage 314. In some examples, the handle support structure 332 may include an opening to allow the flexible linkage 314 to lay approximately flush with the interior surface 313 when the handle 310 is in the closed position. The drive wedge 324 may force the catch engagement device 328-1, 328-2 to disengage from the catch in response to a tensile force applied to the drive wedge 324 by the flexible linkage 314.

In some examples, the catch engagement devices 328-1, 328-2 may move away from each other within a channel 334 in response to a force applied by the drive wedge 324 as the handle 310 moves to the open position. Thus, the catch engagement devices 328-1, 328-2 may move from a first position to a second position in response to movement of the drive wedge 324. A spring 430 may apply a bias force to return the catch engagement devices 328-1, 328-2 from the second position to the first position once the handle 310 moves from the open position to the closed position.

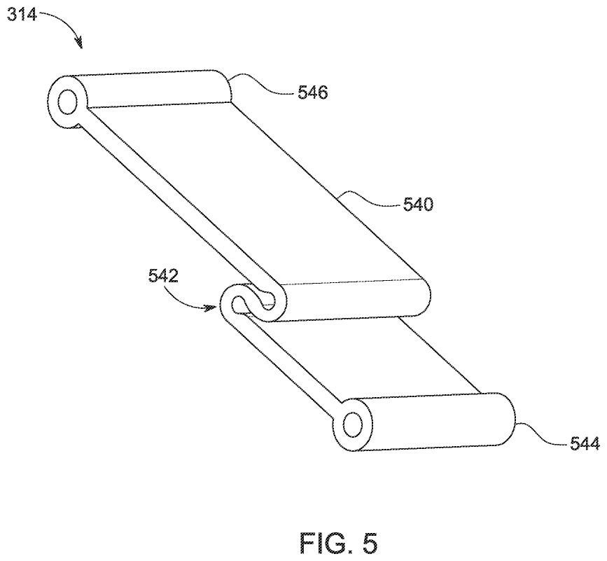

FIG. 5 is a perspective view of the flexible linkage 314, according to and example. The flexible linkage 314 includes a body 540 formed with a fold structure 542 that unfolds from a first position to a second position under tension. The flexible linkage 314 includes a first end 544 of the body 540 to couple to a handle (FIG. 3, 310) of a panel release mechanism (FIG. 2, 208). The flexible linkage 314 also includes a second end 546 of the body 540 to couple to a latch mechanism (FIG. 3, 312).

In the example of FIG. 5, the first end 544 and the second end 546 each terminate in a hole structure to receive a pin. For example, the first end 544 may connect to a first pin (FIG. 4, 426) at the handle (FIG. 4, 310) and the second end 546 may connect to a second pin (FIG. 4, 422) at the drive wedge (FIG. 4, 422).

The flexible linkage 314 may become taut upon unfolding. Thus, as opposed to a spring (e.g., a coil string), the flexible linkage 314 may provide elasticity as the fold structure 542 unfolds and may provide stiffness in tension once the flexible linkage 314 has unfolded. The fold structure 542 may fold back to the first position when the tension is removed. The flexible linkage 314 is shown in the first position in FIG. 5.

In some examples, the flexible linkage 314 is formed from a flexible material. In some examples, flexible linkage 314 may be formed entirely from a single material. In some examples, the flexible linkage 314 may be formed from an elastomer (e.g., rubber). For example, the flexible linkage 314 may be formed from a thermoplastic elastomer (e.g., TPA). In some examples, the flexible linkage 314 may be molded or three-dimensionally (3D) printed from a single, monolithic material.

In some examples, the fold structure 542 may be formed from a different material than other portions of the flexible linkage 314. For example, the fold structure 542 may be formed from an elastomer that provides flexibility as the fold structure 542 unfolds and stiffness when unfolded. However, other portions of the flexible linkage 314 may be a different material. For instance portions of the flexible linkage 314 outside the fold structure 542 may be a rigid material (e.g., metal, plastic, ceramic, etc.).

In some examples, the fold structure 542 may be formed as a double curve. In this case, the flexible linkage 314 may fold back on itself twice. In some examples, the double curve may include a length of material connecting the curves. The length of this material may be determined based on a desired stiffness of the flexible linkage 314 and the position of the handle when the flexible linkage 314 is to begin actuating the latch mechanism 312. Because the fold structure 542 is formed with a folded geometry, when in an un-tensioned state, the flexible linkage 314 may return to the folded state, referred to herein as a retracted position.

In some examples, the wall thickness of the fold structure 542 is less than the wall thickness of the body 540. By reducing the wall thickness of the fold structure 542, stress may be reduced in the fold structure 542 as the fold structure 542 cycles through folding and unfolding.

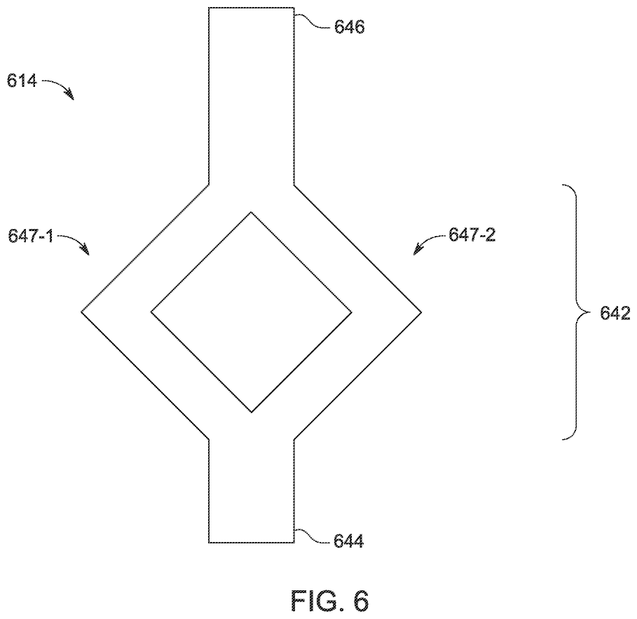

Other geometries may be used to implement the fold structure. For example, FIG. 6 illustrates an example where the fold structure 642 is formed as a pair of chevrons 647-1, 647-2 (e.g., V-shapes) when in an un-tensioned state. Each chevron 647-1, 647-2 may have a pair of legs that meet at an angle. As a tensile force is applied to the first end 644 and the second end 646, the chevrons 647-1, 647-2 elongate (i.e., unfold) such that the angle between the legs of the chevrons 647-1, 647-2 becomes more obtuse. In other examples, the fold structure may be formed as a zig-zag shape.

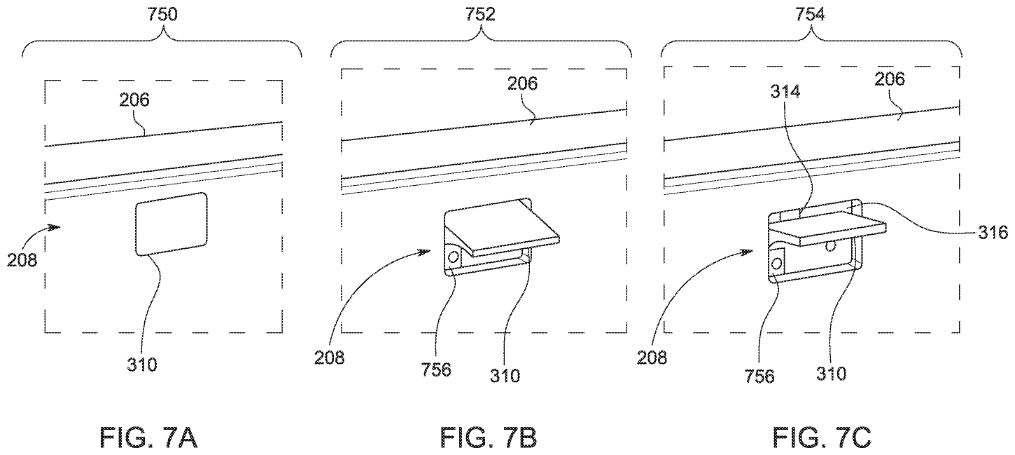

FIGS. 7A-7C illustrate a front perspective view of the panel release mechanism 208 moving from a closed position 750 to an open position 754, according to an example. In FIG. 7A, the handle 310 of the panel release mechanism 208 is in a closed position 750 such that the handle 310 lays flush with the panel 206.

In FIG. 7B, a force exerted on the handle 310 (e.g., by the hand of a user) may cause the handle 310 to rotate to a partial-open position 752. In this example, the panel 206 includes a lock 756. When in the closed position 750, the handle 310 hides the lock 756. When the handle 310 is in the partial-open position 752, the handle 310 reveals the lock 756 without actuating the latch mechanism. As the handle 310 rotates from the closed position 750 to the partial-open position 752, the flexible linkage 314 may unfold without actuating the latch mechanism.

In FIG. 7C, if the lock 756 is unlocked, the handle 310 may continue to rotate through to the open position 754. As the handle 310 rotates from the partial-open position 752 to the open position 754, the flexible linkage 314 may be taut and may actuate the latch mechanism to release the panel 206 from the enclosure. In the open position 754, the flexible linkage 314 is viewable through the opening 316 in the panel 206.

FIGS. 8A-8C illustrate a back perspective view of the panel release mechanism 208 moving from the closed position 750 to the open position 754, according to an example. The state of the panel release mechanism 208 in FIGS. 8A-8C correspond to the state of the panel release mechanism 208 in FIGS. 7A-7C.

In FIG. 8A, the panel release mechanism 208 is in the closed position 750. In this case, the flexible linkage 314 is connected to the handle 310 at a first end of the flexible linkage 314, and connected to the latch mechanism (e.g., the drive wedge 324) at a second end of the flexible linkage 314. The flexible linkage 314 includes a fold structure (e.g., FIG. 5, 542) that unfolds from a retracted position to an extended position when the handle 310 is rotated. The flexible linkage 314 is shown in the retracted position in FIG. 8A. When in the retracted position, a first portion of the flexible linkage 314 may lay flush with the interior surface of the panel 206. A second portion of the flexible linkage 314 may reside within a channel of the drive wedge 324.

In FIG. 8B, the handle 310 rotates to a partial-open position 752. When the handle 310 is in the partial-open position 752, the handle 310 reveals the opening 316 of the panel 206. As the handle 310 rotates to the partial-open position 752, the flexible linkage 314 unfolds. It should be noted that the flexible linkage 314 does not actuate the latch mechanism 312 while the fold structure (FIG. 5, 542) unfolds. The flexible linkage 314 is shown in the extended position in FIG. 8B.

In FIG. 7C, the handle 310 continues to rotate through to the open position 754. Once the flexible linkage 314 finishes unfolding, the flexible linkage 314 may begin to actuate the latch mechanism 312. For example, as the handle 310 rotates from the partial-open position 752 to the open position 754, the flexible linkage 314 may be taut and may actuate the latch mechanism 312 to release the panel 206 from the enclosure. For example, the flexible linkage 314 may pull the drive wedge 324 down. As the drive wedge 324 moves down, the catch engagement devices 328-1, 328-2 move apart. A spring 430 applies a bias force to push the catch engagement devices 328-1, 328-2 back together as the handle moves back to the closed position 750 and the flexible linkage 314 folds back to the retracted position. As the spring 430 pulls the catch engagement devices 328-1, 328-2 back together, the drive wedge 324 moves up to a first position.

In some examples, the handle 310 may include a stop 860 formed on the back surface of the handle 310. The stop 860 may project out from the back surface of the handle 310. The stop 860 may be sized and positioned to engage the panel 206 (e.g., at the handle support structure 332). As the handle 310 reaches the open position 754, the stop 860 engages the panel 206, thus preventing further rotation of the handle 310 and restricting the flexible linkage 314 from further actuating the latch mechanism 312.

What is claimed is:

1. A flexible linkage for a panel release mechanism, comprising:
a body formed with a fold structure that unfolds from a first position to a second position under tension and becomes taut upon unfolding;
a first end of the body to couple to a handle of the panel release mechanism; and
a second end of the body to couple to a latch mechanism.

2. The flexible linkage of claim 1, wherein the fold structure is to fold back to the first position when the tension is removed.

3. The flexible linkage of claim 1, wherein the flexible linkage is formed from a single material.

4. The flexible linkage of claim 3, wherein the single material comprises a thermoplastic elastomer.

5. The flexible linkage of claim 1, wherein the fold structure comprises a double curve.

6. The flexible linkage of claim 1, wherein the fold structure comprises a pair of chevrons.

7. The flexible linkage of claim 1, wherein a wall thickness of the fold structure is less than a wall thickness of the body.

8. A panel release mechanism, comprising:
a handle to rotate about an axis from a closed position to an open position;
a latch mechanism to engage a catch; and
a flexible linkage connected to the handle at a first end of the flexible linkage, and connected to the latch mechanism at a second end of the flexible linkage, the flexible linkage comprising:
a fold structure to allow the flexible linkage to unfold when the handle is partially rotated to the open position, and to actuate the latch mechanism after unfolding.

9. The panel release mechanism of claim 8, wherein the fold structure is to become taut after unfolding.

10. The panel release mechanism of claim 8, wherein unfolding of the fold structure generates a bias force.

11. The panel release mechanism of claim 10, wherein the bias force generated by the fold structure is to be exerted on the handle to cause the handle to return to the closed position.

12. An access panel assembly for an enclosure, comprising:
a panel to provide access to the enclosure, the panel comprising an opening;
a handle connected to the panel at the opening of the panel, the handle to rotate about an axis from a closed position to an open position;
a latch mechanism connected to an interior surface of the panel, the latch mechanism to selectively engage a catch located on the enclosure; and
a flexible linkage connected to the handle at a first end of the flexible linkage, and connected to the latch mechanism at a second end of the flexible linkage, the flexible linkage comprising a fold structure to unfold from a retracted position to an extended position when the handle is rotated, and to actuate the latch mechanism after unfolding.

13. The access panel assembly of claim 12, wherein the flexible linkage does not actuate the latch mechanism while the fold structure unfolds.

14. The access panel assembly of claim 12, wherein the latch mechanism comprises:
a catch engagement device to engage the catch located on the enclosure; and
a drive wedge coupled to the flexible linkage, the drive wedge to force the catch engagement device to disengage from the catch in response to a tensile force applied to the drive wedge by the flexible linkage.

15. The access panel assembly of claim 12, wherein flexible linkage is connected to the handle by a linkage pin offset from the axis of rotation of the handle.
